(19) United States
(12) Patent Application Publication
(10) Pub. No.: US 2026/0075900 A1
(43) Pub. Date: Mar. 12, 2026

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Kouta TOMITA, Nonoichi Ishikawa (JP)

(21) Appl. No.: 19/012,178

(22) Filed: Jan. 7, 2025

(30) Foreign Application Priority Data
Sep. 11, 2024 (JP) 2024-157683

(51) Int. Cl. H10D 62/10; H10D 64/00

(52) U.S. Cl. CPC H10D 62/125; H10D 62/126; H10D 64/117

(57) ABSTRACT

A semiconductor device according to an embodiment includes a first electrode, a second electrode, a semiconductor layer, a first semiconductor region of a first conductivity type, a second semiconductor region of a second conductivity type, a third electrode, and a third semiconductor region of the first conductivity type. The first semiconductor region is provided in the semiconductor layer. The second semiconductor region is located on the first semiconductor region. The third electrode is provided in the second semiconductor region via a first insulating region. The third semiconductor region is located between the second semiconductor region and the second electrode. The semiconductor layer includes a first portion, and a second portion in which a width of the third electrode is larger than that in the first portion, and a length of the second portion in the second direction is smaller than that of the first portion.

### CROSS-REFERENCE TO RELATED APPLICATIONS

This application is based upon and claims the benefit of priority from the prior Japanese Patent Application No. 2024-157683, filed on Sep. 11, 2024; the entire contents of which are incorporated herein by reference.

### FIELD

Embodiments described herein relate generally to a semiconductor device.

### BACKGROUND

In a semiconductor device such as a metal oxide semiconductor field effect transistor (MOSFET), an on-resistance is desirably low. However, when, for example, a cell pitch is miniaturized or a channel length is shortened in order to reduce the on-resistance, the transconductance of the semiconductor device increases, and a safe operating area (SOA) may be narrowed. That is, the on-resistance and the safe operating area are in a trade-off relationship.

### BRIEF DESCRIPTION OF THE DRAWINGS

FIG. 1 is a plan view of a semiconductor device according to an embodiment;

FIG. 2A is a cross-sectional view of a gate normal width portion in the semiconductor device according to the embodiment;

FIG. 2B is a cross-sectional view of a gate wide portion in the semiconductor device according to the embodiment;

FIG. 3 is a graph of a simulation result indicating a relationship between a mesa width and a threshold voltage in the semiconductor device according to the embodiment;

FIG. 4 is a cross-sectional view of the gate normal width portion and the gate wide portion for explaining an example of a manufacturing step of the semiconductor device according to the embodiment;

FIG. 5 is a cross-sectional view of the gate normal width portion and the gate wide portion for explaining an example of a manufacturing step of the semiconductor device according to the embodiment, following FIG. 4;

FIG. 6A is a cross-sectional view of the gate normal width portion for explaining an example of a manufacturing step of the semiconductor device according to the embodiment, following FIG. 5;

FIG. 6B is a cross-sectional view of the gate wide portion for explaining an example of a manufacturing step of the semiconductor device according to the embodiment, following FIG. 5;

FIG. 7A is a cross-sectional view of the gate normal width portion for explaining an example of a manufacturing step of the semiconductor device according to the embodiment, following FIG. 6A;

FIG. 7B is a cross-sectional view of the gate wide portion for explaining an example of a manufacturing step of the semiconductor device according to the embodiment, following FIG. 6B;

FIG. 8A is a cross-sectional view of the gate normal width portion for explaining an example of a manufacturing step of the semiconductor device according to the embodiment, following FIG. 7A;

FIG. 8B is a cross-sectional view of the gate wide portion for explaining an example of a manufacturing step of the semiconductor device according to the embodiment, following FIG. 7B;

FIG. 9A is a cross-sectional view of the gate normal width portion for explaining an example of a manufacturing step of the semiconductor device according to the embodiment, following FIG. 8A;

FIG. 9B is a cross-sectional view of the gate wide portion for explaining an example of a manufacturing step of the semiconductor device according to the embodiment, following FIG. 8B;

FIG. 10 is a plan view of a semiconductor device according to Modification 1; and

FIG. 11 is a plan view of a semiconductor device according to Modification 2.

### DETAILED DESCRIPTION

A semiconductor device according to an embodiment includes a first electrode, a second electrode, a semiconductor layer, a first semiconductor region of a first conductivity type, a second semiconductor region of a second conductivity type, a third electrode, and a third semiconductor region of the first conductivity type. The semiconductor layer is provided between the first electrode and the second electrode. The first semiconductor region is provided in the semiconductor layer and is located on the first electrode. The second semiconductor region is provided in the semiconductor layer and is located on the first semiconductor region. The third electrode is provided in the second semiconductor region via a first insulating region, and extends in a second direction orthogonal to a first direction from the first electrode toward the second electrode. The third semiconductor region is provided in the semiconductor layer and is located between the second semiconductor region and the second electrode. The semiconductor layer includes a first portion in which the third electrode has a first width and extends in the second direction, and a second portion in which the third electrode has a second width larger than the first width. A length of the second portion in the second direction is smaller than a length of the first portion in the second direction.

Hereinafter, embodiments according to the present invention will be described with reference to the drawings. The embodiments do not limit the present invention. The drawings are schematic or conceptual, and the ratio of each portion and the like are not necessarily the same as actual ones. In the specification and the drawings, elements similar to those described above with respect to the previously described drawings are denoted by the same reference numerals, and the detailed description thereof is appropriately omitted.

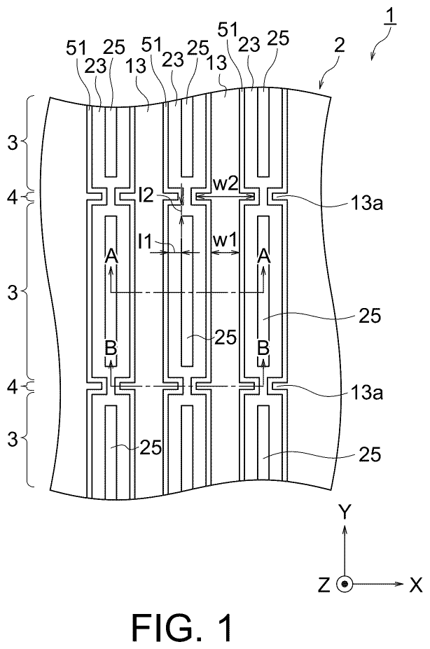

In addition, for convenience of description, an XYZ orthogonal coordinate system is adopted as illustrated in FIG. 1 and the like. A Z-axis direction is a stacking direction (thickness direction) of the semiconductor device. In addition, in the Z-axis direction, a source electrode side is also referred to as “upper”, and a drain electrode side is also referred to as “lower”. However, this expression is for convenience and independent of the direction of gravity. The Z-axis direction is a first direction in the claims. A Y-axis direction is a second direction in the claims. An X-axis direction is a third direction in the claims.

In addition, in the following description, notations of n⁺, n, and n⁻, and p⁺, p, and p⁻ may be used to represent the relative level of impurity concentration in each conductivity type. That is, n⁺ indicates that an n-type impurity concentration is relatively higher than n, and n⁻ indicates that the n-type impurity concentration is relatively lower than n. In addition, p⁺ indicates that a p-type impurity concentration is relatively higher than p, and p⁻ indicates that the p-type impurity concentration is relatively lower than p. When both the p-type impurity and the n-type impurity are contained in each region, these notations represent the relative level of the net impurity concentration after the impurities have been compensated for. The n type, n⁺ type, and n⁻ type are examples of a first conductivity type in the claims. The p type, p⁺ type, and p⁻ type are examples of a second conductivity type in the claims. Note that in the following description, the n-type and the p-type may be reversed. That is, the first conductivity type may be p-type.

In addition, the impurity concentration of the semiconductor region can be measured by, for example, secondary ion mass spectrometry (SIMS). In addition, the relative level of the impurity concentration can also be determined from the level of a carrier concentration obtained by, for example, scanning capacitance microscopy (SCM).

In addition, a dimension such as the width of the semiconductor region can be measured by, for example, analysis of a surface and/or a cross section by a transmission electron microscope (TEM), an energy dispersive X-ray spectroscopy (EDX), or a scanning electron microscope (SEM).

Note that terms such as “identical”, “same”, and “equal”, dimensions, values of physical characteristics, and the like, which specify shapes, geometric conditions, physical characteristics, and the degrees thereof, used in the present specification, are interpreted including a range in which similar functions can be expected, without being bound by a strict meaning.

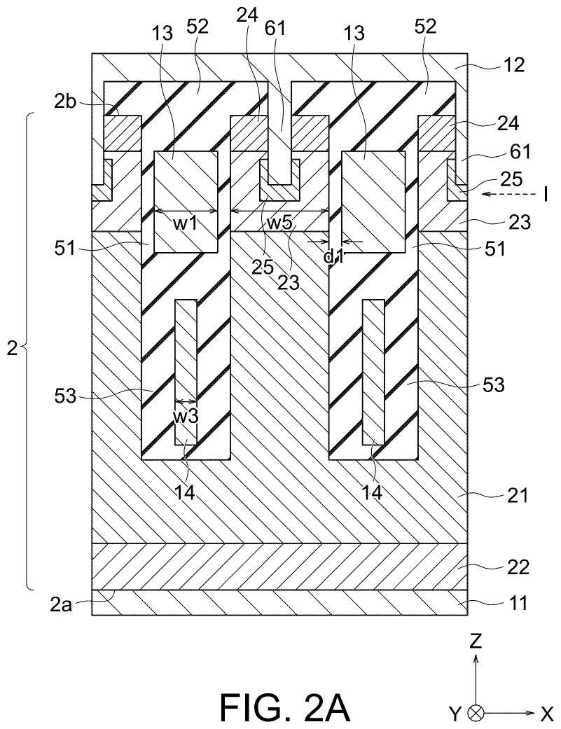

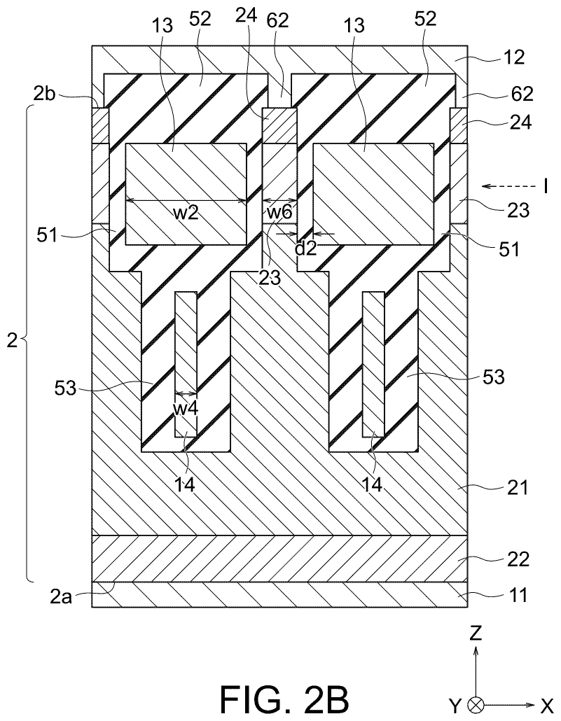

A semiconductor device 1 according to an embodiment will be described with reference to FIGS. 1, 2A, and 2B. FIG. 1 is a plan view of the semiconductor device 1 according to the embodiment, and is a plan view at a height position I in FIGS. 2A and 2B. FIG. 2A is a cross-sectional view of a gate normal width portion 3 in the semiconductor device 1 according to the embodiment, and is a cross-sectional view taken along line A-A in FIG. 1. FIG. 2B is a cross-sectional view of a gate wide portion 4 in the semiconductor device 1 according to the embodiment, and is a cross-sectional view taken along line B-B in FIG. 1.

The semiconductor device 1 is, for example, a vertical MOSFET. More specifically, the semiconductor device 1 is a vertical MOSFET having a structure in which a field plate electrode (FP electrode) and a gate electrode are buried in the identical trench. Note that the semiconductor device 1 may be a vertical MOSFET having a structure in which the FP electrode and the gate electrode are buried in different trenches. Alternatively, the semiconductor device 1 may be a vertical transistor such as an insulated gate bipolar transistor (IGBT).

As illustrated in FIGS. 2A and 2B, the semiconductor device 1 according to the present embodiment includes a semiconductor layer 2, a drain electrode 11, a source electrode 12, a gate electrode 13, an FP electrode 14, an insulating region (gate insulating film) 51, an insulating region (interlayer insulating film) 52, an insulating region (FP insulating film) 53, a conductive portion 61, and a conductive portion 62.

The semiconductor layer 2 is provided between the drain electrode 11 and the source electrode 12. The semiconductor layer 2 includes a lower surface 2a and an upper surface 2b opposite to the lower surface 2a.

In addition, as illustrated in FIG. 1, the semiconductor layer 2 has the gate normal width portion 3 and the gate wide portion 4. The gate normal width portion 3 is a portion in which the gate electrode 13 has a width (first width) w1 and extends in the Y-axis direction. The gate wide portion 4 is a portion in which the gate electrode 13 has a width (second width) w2. The width w2 is larger than the width w1. That is, the length of the gate electrode 13 in the X-axis direction in the gate wide portion 4 is larger than the length of the gate electrode 13 in the X-axis direction in the gate normal width portion 3. The gate normal width portion 3 is an example of a first portion in the claims. The gate wide portion 4 is an example of a second portion in the claims. As illustrated in FIG. 1, the gate normal width portion 3 and the gate wide portion 4 are alternately provided along the Y-axis direction.

In addition, the length of the gate wide portion 4 in the Y-axis direction is smaller than the length of the gate normal width portion 3 in the Y-axis direction. That is, the gate electrode 13 is configured to be locally wide in the gate wide portion 4. In addition, in the gate wide portion 4, the gate electrode 13 has a protrusion 13a protruding into a base region 23 via the insulating region 51. Note that the ratio of the gate wide portion 4 to the gate normal width portion 3 in the Y-axis direction is not limited to the example of FIG. 1. For example, the ratio of the gate wide portion 4 to the gate normal width portion 3 in the Y-axis direction may be larger or smaller than that in the example of FIG. 1. Alternatively, the gate wide portion 4 may be provided more densely or less densely than that in the example of FIG. 1.

As illustrated in FIG. 1, a plurality of the gate electrodes 13 are provided, and each extend in the Y-axis direction. That is, the semiconductor device 1 has a so-called stripe structure. In the present embodiment, the center of the gate normal width portion 3 in the Y-axis direction between the gate electrodes 13 adjacent to each other is along the X-axis direction, and the center of the gate wide portion 4 in the Y-axis direction between the gate electrodes 13 adjacent to each other is along the X-axis direction. That is, a plurality of the gate normal width portions 3 are continuously provided along the X-axis direction, and a plurality of the gate wide portions 4 are continuously provided along the X-axis direction.

The semiconductor layer 2 may be an epitaxial layer, a semiconductor substrate, or a semiconductor substrate and an epitaxial layer disposed on the semiconductor substrate. In the present embodiment, the semiconductor layer 2 is silicon (Si). In this case, for example, arsenic (As), phosphorus (P), or antimony (Sb) is used as the n-type impurity, and for example, boron (B) is used as the p-type impurity. Note that the semiconductor layer 2 may be made of a compound semiconductor such as silicon carbide (SiC) or gallium nitride (GaN).

As illustrated in FIGS. 2A and 2B, for example, a drift region 21, a drain region 22, the base region 23, a source region 24, and a high-concentration region 25 are provided in the semiconductor layer 2. Details of these regions will be described later.

The drain electrode 11 functions as a drain electrode of the MOSFET. The drain electrode 11 is provided on the lower surface 2a of the semiconductor layer 2. The drain electrode 11 is in contact with the drain region 22 and is electrically connected to the drain region 22. The drain electrode 11 is an example of a first electrode in the claims. The drain electrode 11 is made of, for example, copper (Cu), titanium (Ti), tungsten (W), aluminum (Al), or the like.

The source electrode 12 functions as a source electrode of the MOSFET. The source electrode 12 is provided on the upper surface 2b of the semiconductor layer 2 via the insulating region 52. As illustrated in FIG. 2A, the source electrode 12 is electrically connected to the source region 24 and the high-concentration region 25 via the conductive portion 61 in the gate normal width portion 3. In addition, as illustrated in FIG. 2B, the source electrode 12 is electrically connected to the source region 24 via the conductive portion 62 in the gate wide portion 4. The source electrode 12 is an example of a second electrode in the claims. The source electrode 12 is made of, for example, copper (Cu), titanium (Ti), tungsten (W), aluminum (Al), or the like. Note that the insulating region 52 contains, for example, a silicon oxide or a silicon nitride.

The gate electrode 13 functions as a gate electrode of the MOSFET. The gate electrode 13 is provided in the base region 23 via the insulating region 51. The gate electrode 13 is electrically insulated from the semiconductor layer 2 by the insulating region 51. The gate electrode 13 is an example of a third electrode in the claims. The gate electrode 13 is made of, for example, polysilicon containing p-type or n-type impurities. When a voltage is applied to the gate electrode 13, a channel is formed in the base region 23, and carriers flow between the drift region 21 and the source region 24. As a result, the MOSFET is brought into an on-state.

As illustrated in FIGS. 2A and 2B, in the present embodiment, a distance d1 between the gate electrode 13 and the base region 23 along the X-axis direction in the gate normal width portion 3 is equal to a distance d2 between the gate electrode 13 and the base region 23 along the X-axis direction in the gate wide portion 4. Here, the distance d1 corresponds to the thickness of the insulating region 51 in the gate normal width portion 3, and the distance d2 corresponds to the thickness of the insulating region 51 in the gate wide portion 4. Note that the distance d1 may be different from the distance d2.

The FP electrode 14 is provided in the gate normal width portion 3 and the gate wide portion 4 of the semiconductor layer 2 via the insulating region 53. The FP electrode 14 is electrically insulated from the semiconductor layer 2 by the insulating region 53, and is electrically connected to the source electrode 12, for example, at an end of the semiconductor layer 2 (not illustrated) in the Y-axis direction. The FP electrode 14 is an example of a fourth electrode in the claims. In the present embodiment, the FP electrode 14 is located below the gate electrode 13 and extends in the Y-axis direction. The FP electrode 14 is made of, for example, polysilicon containing p-type or n-type impurities. Note that the FP electrode 14 may be provided in the semiconductor layer 2 via an insulating region different from the insulating region 53. In addition, the FP electrode 14 may be provided so as to extend in a direction other than the Y-axis direction (for example, the X-axis direction).

As illustrated in FIGS. 2A and 2B, the FP electrode 14 has a width w3 in the gate normal width portion 3 and a width w4 in the gate wide portion 4. In the present embodiment, the width w3 is equal to the width w4. Note that the width w3 may be different from the width w4.

The insulating region 51 and the insulating region 53 are provided so as to cover side walls of a plurality of trenches provided on the upper surface 2b of the semiconductor layer 2. The insulating region 51 and the insulating region 53 are examples of a first insulating region and a second insulating region, respectively, in the claims. Each of the insulating region 51 and the insulating region 53 includes, for example, a silicon oxide or a silicon nitride.

The conductive portion 61 is provided in the gate normal width portion 3, penetrates the source region 24, and electrically connects the source region 24 and the high-concentration region 25 to the source electrode 12. The conductive portion 61 is an example of a first conductive portion in the claims. The conductive portion 61 is made of, for example, the same material as the source electrode 12. Note that the conductive portion 61 may be made of a material different from that of the source electrode 12.

The conductive portion 62 is provided in the gate wide portion 4 and electrically connects the source region 24 and the source electrode 12. A lower end of the conductive portion 62 is located above an upper end of the base region 23. In the present embodiment, the conductive portion 62 does not penetrate the source region 24. More specifically, in the present embodiment, the lower end of the conductive portion 62 is located at the same height as the upper surface 2b of the semiconductor layer 2. The conductive portion 62 is an example of a second conductive portion in the claims. The conductive portion 62 is made of, for example, the same material as the source electrode 12. Note that the conductive portion 62 may be made of a material different from that of the source electrode 12.

Next, details of each region in the semiconductor layer 2 will be described.

The drift region 21 functions as a drift region of the MOSFET. The drift region 21 is provided in the gate normal width portion 3 and the gate wide portion 4 of the semiconductor layer 2, and is disposed on the drain region 22 (above the drain electrode 11). The drift region 21 is, for example, an n⁻-type semiconductor region. The n-type impurity concentration of the drift region 21 is, for example, 1×10¹⁵ cm⁻³ or more and 2×10¹⁶ cm⁻³ or less.

The drain region 22 functions as a drain region of the MOSFET. The drain region 22 is provided in the gate normal width portion 3 and the gate wide portion 4 of the semiconductor layer 2, is located on the drain electrode 11, and is disposed between the drift region 21 and the drain electrode 11. The drain region 22 is in contact with the drain electrode 11 and is in ohmic contact with the drain electrode 11. The drain region 22 is, for example, an n⁺-type semiconductor region. The n-type impurity concentration of the drain region 22 is, for example, 1×10¹⁸ cm⁻³ or more and 1×10²¹ cm⁻³ or less.

The drift region 21 and the drain region 22 are examples of a first semiconductor region in the claims. Note that the drain region 22 may not be provided. In this case, the drift region 21 is directly provided on the drain electrode 11, and the drain electrode 11 is electrically connected to the drift region 21. Alternatively, the drift region 21 may not be provided. In this case, for example, the drain region 22 is also provided at the position of the drift region 21.

The base region 23 functions as a base region of the MOSFET. The base region 23 is provided in the gate normal width portion 3 and the gate wide portion 4 of the semiconductor layer 2, and is located on the drift region 21. As illustrated in FIG. 1, the base region 23 extends in the Y-axis direction. As illustrated in FIGS. 2A and 2B, the base region 23 has a width w5 in the gate normal width portion 3 and a width w6 in the gate wide portion 4. The width w5 and the width w6 are so-called mesa widths. In the present embodiment, the width w6 is smaller than the width w5. The width w6 is, for example, 0.1 μm or less. The base region 23 is, for example, a p-type semiconductor region. The p-type impurity concentration of the base region 23 is, for example, 1×10¹⁶ cm⁻³ or more and 1×10²⁰ cm⁻³ or less. The base region 23 is an example of a second semiconductor region in the claims.

The source region 24 functions as a source region of the MOSFET. The source region 24 is provided in the gate normal width portion 3 and the gate wide portion 4 of the semiconductor layer 2, and is located between the base region 23 and the source electrode 12. The source region 24 is in ohmic contact with the conductive portion 61 and the conductive portion 62. The source region 24 extends in the Y-axis direction. The source region 24 is, for example, an n⁺-type semiconductor region. The n-type impurity concentration of the source region 24 is, for example, 1×10¹⁸ cm⁻³ or more and 1×10²² cm⁻³ or less. The source region 24 is an example of a third semiconductor region in the claims.

As illustrated in FIG. 2A, the high-concentration region 25 is provided in the base region 23 in the gate normal width portion 3. The high-concentration region 25 is electrically connected to the source electrode 12 via the conductive portion 61. The high-concentration region 25 is, for example, a p⁺-type semiconductor region. That is, the impurity concentration of the high-concentration region 25 is higher than the impurity concentration of the base region 23. The p-type impurity concentration of the high-concentration region 25 is, for example, 1×10¹⁸ cm⁻³ or more and 1×10²¹ cm⁻³ or less. The high-concentration region 25 is an example of a fourth semiconductor region in the claims.

As illustrated in FIG. 1, the high-concentration region 25 does not extend into the gate wide portion 4. That is, the high-concentration region 25 is not provided in the gate wide portion 4. In the present embodiment, the high-concentration region 25 is not provided at a boundary between the gate normal width portion 3 and the gate wide portion 4. In addition, the high-concentration region 25 is provided away from the boundary. In the example of FIG. 1, a length l1 of the base region 23 between the high-concentration region 25 and the insulating region 51 in the X-axis direction is equal to a length l2 of the base region 23 between the high-concentration region 25 and the insulating region 51 in the Y-axis direction. Note that the length l1 may be different from the length l2. In addition, the high-concentration region 25 may be provided up to the boundary between the gate normal width portion 3 and the gate wide portion 4.

As described above, the semiconductor device 1 according to the embodiment includes the drain electrode 11, the source electrode 12, the semiconductor layer 2, the drift region 21 and the drain region 22 of the first conductivity type, the base region 23 of the second conductivity type, the gate electrode 13, and the source region 24 of the first conductivity type. The semiconductor layer 2 is provided between the drain electrode 11 and the source electrode 12. The drift region 21 and the drain region 22 are provided in the semiconductor layer 2 and are located on the drain electrode 11. The base region 23 is provided in the semiconductor layer 2 and is located on the drift region 21. The gate electrode 13 is provided in the base region 23 via the insulating region 51, and extends in the Y-axis direction orthogonal to the Z-axis direction from the drain electrode 11 toward the source electrode 12. The source region 24 is provided in the semiconductor layer 2 and is located between the base region 23 and the source electrode 12. The semiconductor layer 2 includes the gate normal width portion 3 in which the gate electrode 13 has the width w1 and extends in the Y-axis direction, and the gate wide portion 4 in which the gate electrode 13 has the width w2 larger than the width w1. The length of the gate wide portion 4 in the Y-axis direction is smaller than the length of the gate normal width portion 3 in the Y-axis direction.

In the present embodiment, in the gate wide portion 4, the gate electrodes 13 sandwiching the base region 23 are close to each other as compared with those in the gate normal width portion 3. Therefore, in the gate wide portion 4, an inversion layer is easily formed in the base region 23. As a result, a threshold voltage of the gate wide portion 4 becomes smaller than a threshold voltage of the gate normal width portion 3. For example, when a drive voltage is applied to the gate electrode 13, the channel is first turned on in the gate wide portion 4 while the voltage is low, and the channel remains off in the gate normal width portion 3. Thereafter, when the voltage increases, the channel is turned on also in the gate normal width portion 3. As a result, since the transconductance of the semiconductor device 1 is reduced, a safe operating area can be secured even when the on-resistance is reduced. For example, even in a case where the cell pitch of the semiconductor device 1 is miniaturized or the channel length is shortened in order to reduce the on-resistance, the safe operating area can be secured. As described above, according to the present embodiment, a trade-off between the on-resistance and the safe operating area can be improved.

In addition, in the present embodiment, the width w6 of the base region 23 in the gate wide portion 4 is smaller than the width w5 of the base region 23 in the gate normal width portion 3. As a result, channel mobility in the base region 23 of the gate wide portion 4 is improved, and the on-resistance of the semiconductor device 1 can be reduced as compared with a case where the gate wide portion 4 is not provided.

In addition, in the present embodiment, the gate electrode 13 has the protrusion 13a protruding into the base region 23. As illustrated in FIG. 1, the base region 23 has a region near the protrusion 13a in the gate normal width portion 3 (gate corner region). The gate electrode 13 approaches the gate corner region from two directions (the X-axis direction and the Y-axis direction), and a gate electric field is applied to the gate corner region from the two directions. As a result, the inversion layer is more easily formed in the gate corner region. As a result, the transconductance of the semiconductor device 1 can be further reduced.

In addition, according to the present embodiment, the on-resistance and transconductance of the semiconductor device 1 can be controlled by increasing or decreasing the number of the protrusions 13a, and the degree of freedom in designing the semiconductor device 1 can be improved.

In addition, the semiconductor device 1 according to the present embodiment further includes the high-concentration region 25 provided in the base region 23 in the gate normal width portion 3 and electrically connected to the source electrode 12 via the conductive portion 61. On the other hand, the high-concentration region 25 does not extend to the gate wide portion 4. As a result, the avalanche withstand of the semiconductor device 1 can be improved while maintaining the channel mobility in the gate wide portion 4.

In addition, in the present embodiment, the high-concentration region 25 is provided away from the boundary between the gate normal width portion 3 and the gate wide portion 4. As a result, the formation of the inversion layer in the vicinity of the boundary is promoted, and the transconductance of the semiconductor device 1 can be further reduced. Note that the high-concentration region 25 may be provided up to the boundary between the gate normal width portion 3 and the gate wide portion 4. In this case, the avalanche withstand capability of the semiconductor device 1 can be further improved.

In addition, the semiconductor device 1 according to the present embodiment further includes the conductive portion 62 provided in the gate wide portion 4 and electrically connecting the source region 24 and the source electrode 12. As a result, a contact area with the source region 24 can be secured even in the gate wide portion 4, and the on-resistance of the semiconductor device 1 can be further reduced. In addition, the lower end of the conductive portion 62 is located above the upper end of the base region 23. As a result, since the base region 23 is not eroded by the conductive portion 62 in the gate wide portion 4, it is possible to suppress an increase in the threshold voltage of the gate wide portion 4.

In addition, the semiconductor device 1 according to the present embodiment further includes the FP electrode 14 provided in the semiconductor layer 2 via the insulating region 53 and electrically connected to the source electrode 12. As a result, when the MOSFET is in an off-state, a depletion layer extends from the FP electrode 14 to the drift region 21 around the FP electrode 14 by a voltage applied between the drain electrode 11 and the source electrode 12. Since this depletion layer is connected to a depletion layer of the adjacent FP electrode 14, the withstand voltage of the semiconductor device 1 can be improved.

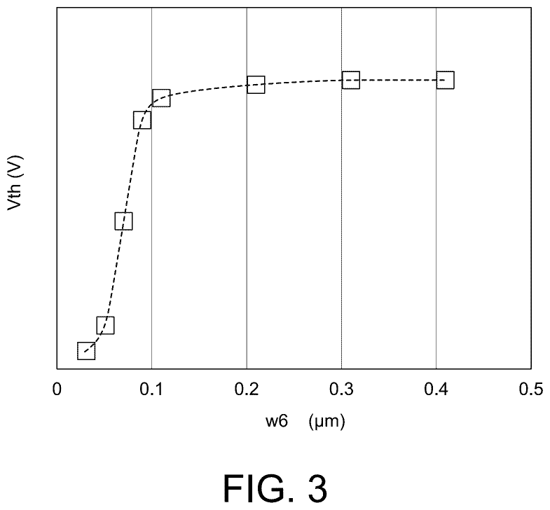

Note that in the present embodiment, the width w6 of the base region 23 in the gate wide portion 4 may be 0.1 μm or less. As a result, the threshold voltage of the gate wide portion 4 can be further reduced. This will be described in detail with reference to FIG. 3. FIG. 3 is a graph of a simulation result representing a relationship between the mesa width (w6) and the threshold voltage (Vth) in the semiconductor device 1 according to the embodiment.

As illustrated in FIG. 3, when the width w6 is 0.1 μm or less, the threshold voltage is greatly reduced as compared with a case where the width w6 is larger than 0.1 μm. Therefore, by setting the width w6 to 0.1 μm or less, the threshold voltage of the gate wide portion 4 can be greatly reduced. In addition, since the threshold voltage of the gate wide portion 4 can be controlled by adjusting the width w6, the degree of freedom in designing the semiconductor device 1 can be improved.

### Method of Manufacturing Semiconductor Device 1

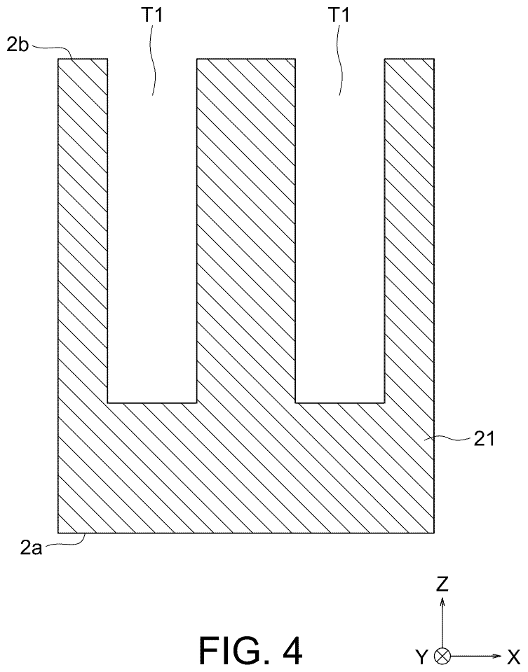

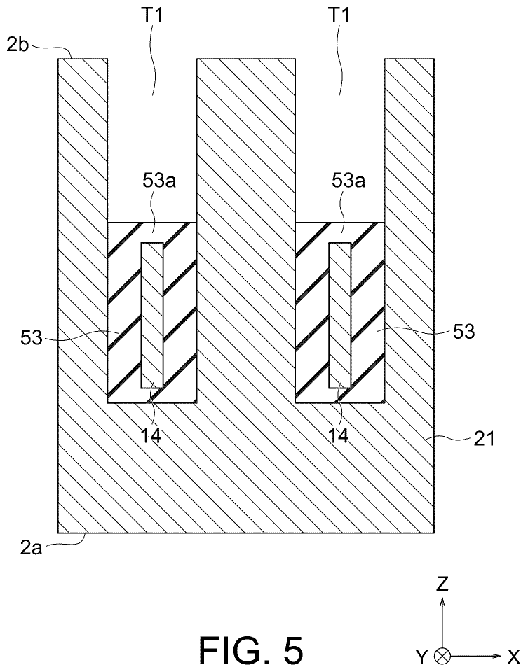

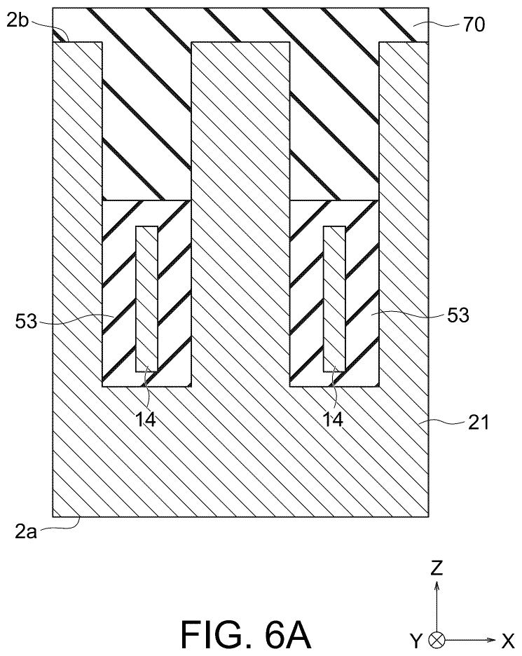

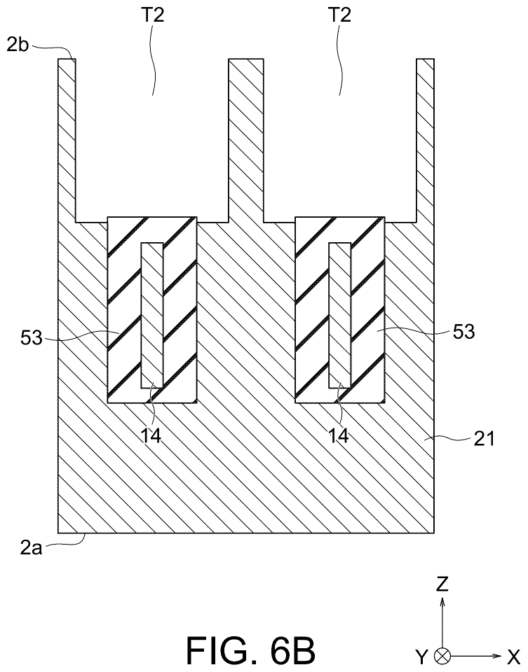

Next, an example of a method of manufacturing the semiconductor device 1 according to the present embodiment will be described with reference to FIGS. 4 to 9B. FIGS. 4 and 5 are cross-sectional views of the gate normal width portion 3 and the gate wide portion 4 for explaining examples of manufacturing steps of the semiconductor device 1 according to the embodiment. FIGS. 6A, 7A, 8A, and 9A are cross-sectional views of the gate normal width portion 3 for explaining examples of manufacturing steps of the semiconductor device 1 according to the embodiment. FIGS. 6B, 7B, 8B, and 9B are cross-sectional views of the gate wide portion 4 for explaining examples of manufacturing steps of the semiconductor device 1 according to the embodiment.

First, as illustrated in FIG. 4, a semiconductor layer including the lower surface 2a and the upper surface 2b opposite to the lower surface 2a is prepared. The semiconductor layer is, for example, an n-type semiconductor substrate. The drift region 21 is provided in the semiconductor layer. In addition, on the upper surface 2b of the semiconductor layer, a trench T1 is formed by reactive ion etching (RIE) or the like.

Next, as illustrated in FIG. 5, the FP electrode 14 and the insulating region 53 are formed in the trench T1. More specifically, first, an insulating region covering an inner wall of the trench T1 and the upper surface 2b of the semiconductor layer is formed by thermal oxidation or the like. Thereafter, a conductive material such as polysilicon is deposited in the insulating region by chemical vapor deposition (CVD) or the like to form the FP electrode 14. Thereafter, a portion of the insulating region that is located above the FP electrode 14 is removed. Thereafter, a silicon oxide or the like is deposited on an upper surface of the FP electrode 14 by CVD or the like to form an insulating region 53a (buried film). Note that in the following description, the insulating region 53a is regarded as a part of the insulating region 53.

Next, as illustrated in FIGS. 6A and 6B, in the gate normal width portion 3, a resist 70 that covers the upper surface 2b of the semiconductor layer and fills the trench T1 is formed. Note that the resist 70 is not formed in the gate wide portion 4. Thereafter, a side wall portion of an upper portion of the trench T1 in the semiconductor layer in the gate wide portion 4 is removed by chemical dry etching (CDE) or the like. As a result, the trench T1 is widened in the gate wide portion 4, and a trench T2 wider than the trench T1 is formed. Thereafter, the resist 70 in the gate normal width portion 3 is removed.

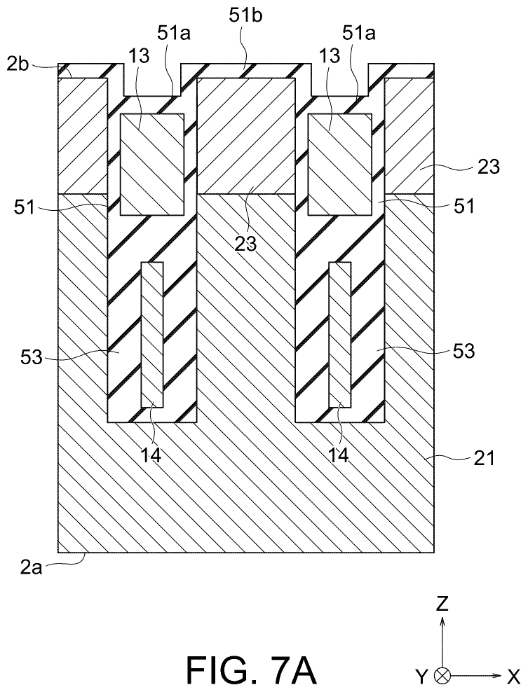

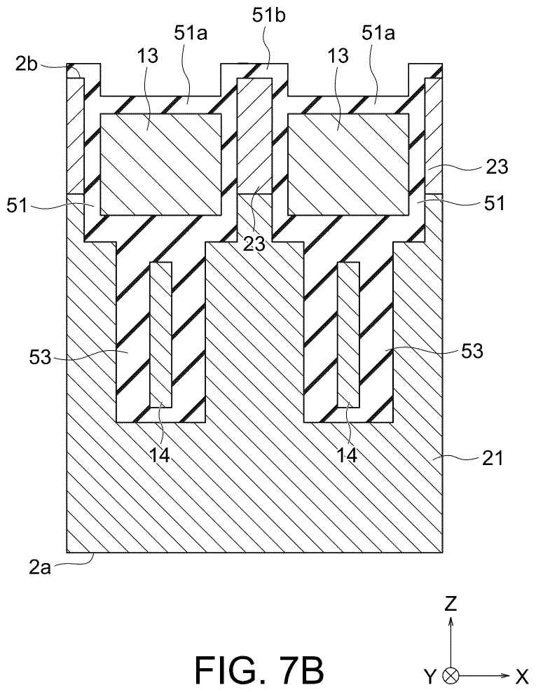

Next, as illustrated in FIGS. 7A and 7B, the gate electrode 13, the base region 23, and the insulating region 51 are formed. More specifically, first, an insulating region covering a side wall of the trench T1 in the gate normal width portion 3, a side wall of the trench T2 in the gate wide portion 4, and the upper surface 2b of the semiconductor layer in the gate normal width portion 3 and the gate wide portion 4 is formed by thermal oxidation or the like. Thereafter, a conductive material such as polysilicon is deposited in the insulating region by CVD or the like to form the gate electrode 13. The width of the gate electrode 13 in the gate wide portion 4 is larger than the width of the gate electrode 13 in the gate normal width portion 3. Thereafter, p-type impurities are ion-implanted into the upper surface 2b of the semiconductor layer to form the base region 23. Thereafter, an insulating region 51a is formed on an upper surface of the gate electrode 13. Note that in the following description, the insulating region 51a is regarded as a part of the insulating region 51. In addition, a portion (insulating region 51b) of the insulating region that is formed on the upper surface 2b of the semiconductor layer is regarded as a part of the insulating region 52 after formation of the insulating region 52 described later.

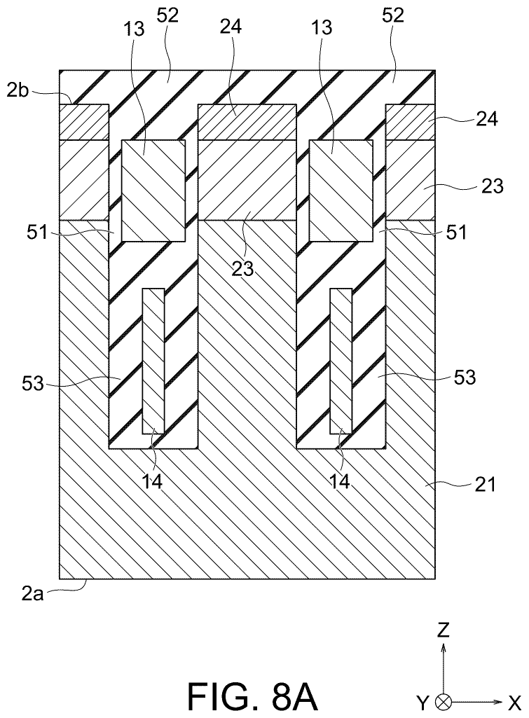

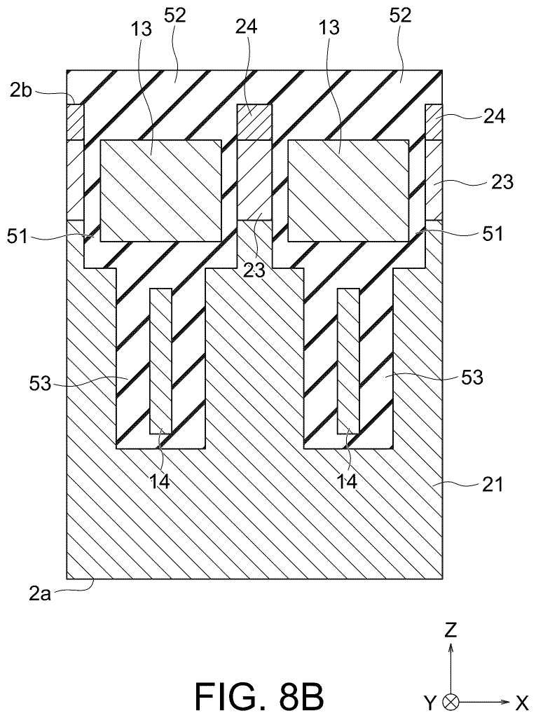

Next, as illustrated in FIGS. 8A and 8B, the source region 24 and the insulating region 52 are formed. More specifically, first, n-type impurities are ion-implanted into the upper surface 2b of the semiconductor layer to form the source region 24. Thereafter, a silicon oxide or the like is deposited on the upper surface 2b of the semiconductor layer by CVD or the like to form the insulating region 52.

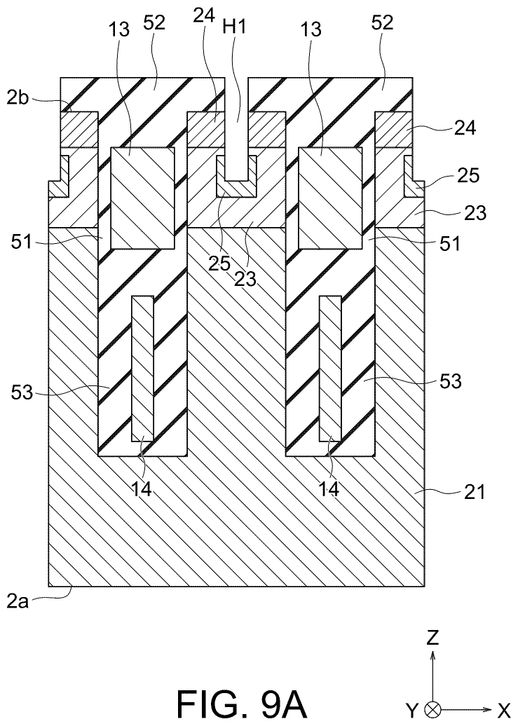

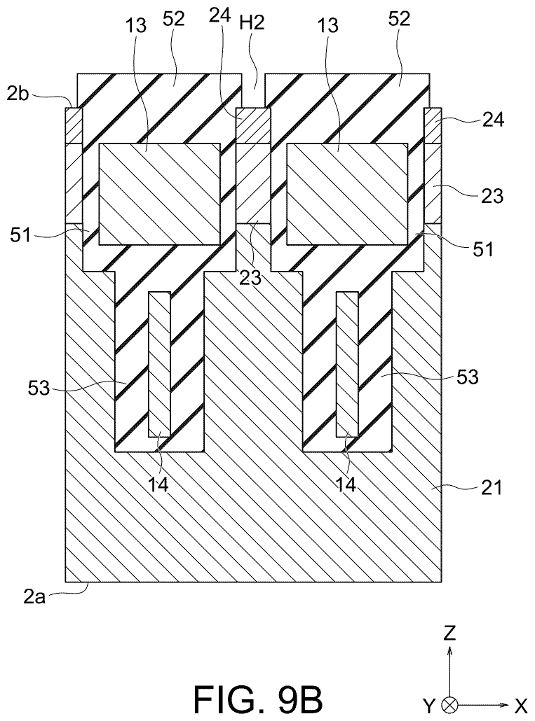

Next, as illustrated in FIGS. 9A and 9B, the high-concentration region 25, an opening H1, and an opening H2 are formed. More specifically, first, an opening reaching an upper end of the source region 24 is formed in the gate normal width portion 3 and the gate wide portion 4 by RIE or the like. As a result, an upper portion of the opening H1 is formed in the gate normal width portion 3, and the opening H2 is formed in the gate wide portion 4. Thereafter, in the gate wide portion 4, a resist that covers the upper surface 2b of the semiconductor layer and fills at least a part of the opening H2 is formed. Note that the resist is not formed in the gate normal width portion 3. Thereafter, a trench penetrating the source region 24 and reaching the base region 23 is formed in the gate normal width portion 3 by silicon RIE or the like. As a result, a lower portion of the opening H1 is formed in the gate normal width portion 3. Thereafter, p-type impurities are ion-implanted into the upper surface 2b of the semiconductor layer to form the high-concentration region 25 at a bottom portion of the opening H1. Thereafter, the resist formed in the gate wide portion 4 is removed.

Thereafter, although not illustrated, n-type impurities are ion-implanted into the lower surface 2a of the semiconductor layer to form the drain region 22. Thereafter, the conductive portion 61, the conductive portion 62, and the source electrode 12 are formed on the upper surface 2b of the semiconductor layer, and the drain electrode 11 is formed on the lower surface 2a of the semiconductor layer. Note that the conductive portion 61 fills the opening H1, and the conductive portion 62 fills the opening H2.

Through the above steps, the semiconductor device 1 is manufactured.

According to the manufacturing method of the present embodiment, the FP electrodes 14 can be collectively formed in the gate normal width portion 3 and the gate wide portion 4. In this case, the width w3 of the FP electrode 14 in the gate normal width portion 3 is equal to the width w4 of the FP electrode 14 in the gate wide portion 4.

In addition, according to the manufacturing method of the present embodiment, the insulating region 51 covering the side wall of the trench T1 in the gate normal width portion 3 and the insulating region 51 covering the side wall of the trench T2 in the gate wide portion 4 can be collectively formed. In this case, the distance d1 between the gate electrode 13 and the base region 23 along the X-axis direction in the gate normal width portion 3 is equal to the distance d2 between the gate electrode 13 and the base region 23 along the X-axis direction in the gate wide portion 4.

Hereinafter, some modifications of the above-described embodiment will be described focusing on differences from the embodiment. Even in each modification described below, it is possible to improve the trade-off between the on-resistance of the semiconductor device and the safe operating area, similarly to the embodiment.

### Modification 1

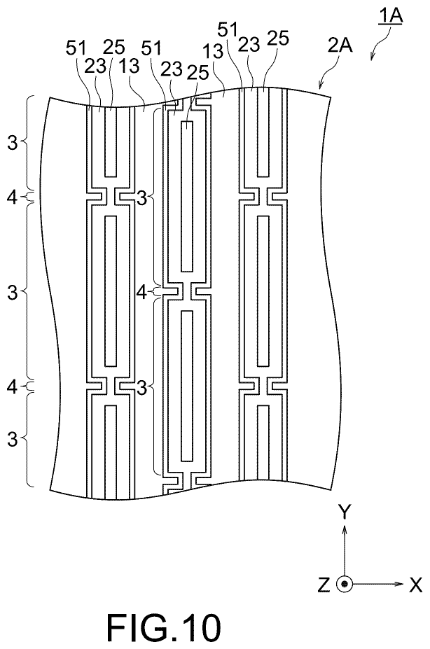

A semiconductor device 1A according to Modification 1 of the embodiment will be described with reference to FIG. 10. FIG. 10 is a plan view of the semiconductor device 1A according to Modification 1.

As illustrated in FIG. 10, in the present modification, the gate normal width portion 3 and the gate wide portion 4 are alternately provided along the X-axis direction. In the example of FIG. 10, the gate wide portions 4 are arranged in a staggered manner in the semiconductor layer 2. More specifically, the center of the gate normal width portion 3 in the Y-axis direction in one gate electrode 13 and the center of the gate wide portion 4 in the Y-axis direction in the adjacent gate electrode 13 are arranged along the X-axis direction. In other words, the position of the center of the gate wide portion 4 in the Y-axis direction is shifted in the Y-axis direction by a half of the length of the gate normal width portion 3 in the Y-axis direction between the gate electrodes 13 adjacent to each other. The present invention is not limited thereto, and the position of the center of the gate wide portion 4 in the Y-axis direction may be shifted in the Y-axis direction by, for example, ⅓ of the length of the gate normal width portion 3 in the Y-axis direction between the gate electrodes 13 adjacent to each other.

According to the present modification, since the gate wide portion 4 having a low threshold voltage is more evenly disposed in the semiconductor device 1A, a current that starts to flow in the semiconductor device 1A can be made uniform when, for example, a drive voltage is applied to the gate electrode 13.

### Modification 2

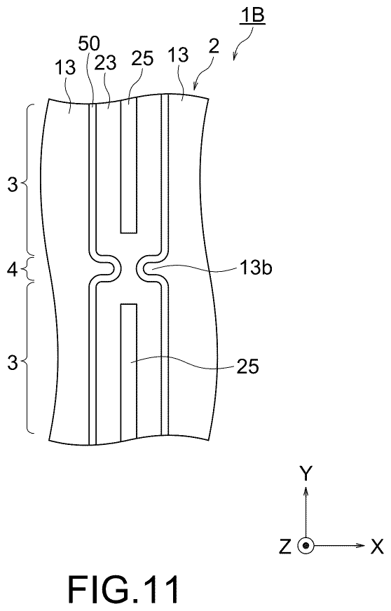

A semiconductor device 1B according to Modification 2 of the embodiment will be described with reference to FIG. 11. FIG. 11 is a plan view of the semiconductor device 1B according to Modification 2.

As illustrated in FIG. 11, in the present modification, the gate electrode 13 includes a protrusion 13b instead of the protrusion 13a. The protrusion 13b has a rounded shape at a tip portion and a root portion. Depending on a method of manufacturing the semiconductor device 1B, the protrusion 13b may have such a shape.

According to the present modification, the degree of freedom of a manufacturing step of the semiconductor device 1B can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a first electrode;
a second electrode;
a semiconductor layer provided between the first electrode and the second electrode;
a first semiconductor region of a first conductivity type provided in the semiconductor layer and located on the first electrode;
a second semiconductor region of a second conductivity type provided in the semiconductor layer and located on the first semiconductor region;
a third electrode provided in the second semiconductor region via a first insulating region and extending in a second direction orthogonal to a first direction from the first electrode toward the second electrode; and
a third semiconductor region of the first conductivity type provided in the semiconductor layer and located between the second semiconductor region and the second electrode, wherein
the semiconductor layer includes a first portion in which the third electrode has a first width and extends in the second direction, and a second portion in which the third electrode has a second width larger than the first width, and
a length of the second portion in the second direction is smaller than a length of the first portion in the second direction.

2. The semiconductor device according to claim 1, wherein in the second portion, the third electrode has a protrusion protruding into the second semiconductor region.

3. The semiconductor device according to claim 2, further comprising
a fourth electrode provided in the semiconductor layer via a second insulating region and electrically connected to the second electrode, wherein
a width of the fourth electrode in the first portion is equal to a width of the fourth electrode in the second portion.

4. The semiconductor device according to claim 2, wherein a width of the second semiconductor region in the second portion is smaller than a width of the second semiconductor region in the first portion.

5. The semiconductor device according to claim 1, further comprising
a fourth semiconductor region provided in the second semiconductor region in the first portion, electrically connected to the second electrode via a first conductive portion, and having an impurity concentration higher than that of the second semiconductor region, wherein
the fourth semiconductor region does not extend to the second portion.

6. The semiconductor device according to claim 5, further comprising
a fourth electrode provided in the semiconductor layer via a second insulating region and electrically connected to the second electrode, wherein
a width of the fourth electrode in the first portion is equal to a width of the fourth electrode in the second portion.

7. The semiconductor device according to claim 5, wherein a width of the second semiconductor region in the second portion is smaller than a width of the second semiconductor region in the first portion.

8. The semiconductor device according to claim 5, wherein the fourth semiconductor region is provided away from a boundary between the first portion and the second portion.

9. The semiconductor device according to claim 8, further comprising
a fourth electrode provided in the semiconductor layer via a second insulating region and electrically connected to the second electrode, wherein
a width of the fourth electrode in the first portion is equal to a width of the fourth electrode in the second portion.

10. The semiconductor device according to claim 8, wherein a width of the second semiconductor region in the second portion is smaller than a width of the second semiconductor region in the first portion.

11. The semiconductor device according to claim 5, further comprising
a second conductive portion provided in the second portion and electrically connecting the third semiconductor region and the second electrode, wherein
a lower end of the second conductive portion is located above an upper end of the second semiconductor region.

12. The semiconductor device according to claim 11, further comprising
a fourth electrode provided in the semiconductor layer via a second insulating region and electrically connected to the second electrode, wherein
a width of the fourth electrode in the first portion is equal to a width of the fourth electrode in the second portion.

13. The semiconductor device according to claim 11, wherein a width of the second semiconductor region in the second portion is smaller than a width of the second semiconductor region in the first portion.

14. The semiconductor device according to claim 1, further comprising
a fourth electrode provided in the semiconductor layer via a second insulating region and electrically connected to the second electrode, wherein
a width of the fourth electrode in the first portion is equal to a width of the fourth electrode in the second portion.

15. The semiconductor device according to claim 14, wherein a width of the second semiconductor region in the second portion is smaller than a width of the second semiconductor region in the first portion.

16. The semiconductor device according to claim 1, wherein a width of the second semiconductor region in the second portion is smaller than a width of the second semiconductor region in the first portion.

17. The semiconductor device according to claim 16, wherein the width of the second semiconductor region in the second portion is 0.1 μm or less.

18. The semiconductor device according to claim 1, wherein a distance between the third electrode and the second semiconductor region along a third direction orthogonal to the first direction and the second direction in the first portion is equal to a distance between the third electrode and the second semiconductor region along the third direction in the second portion.

19. The semiconductor device according to claim 1, wherein a center of the second portion in the second direction between the third electrodes adjacent to each other is along a third direction orthogonal to the first direction and the second direction.

20. The semiconductor device according to claim 1, wherein the first portion and the second portion are alternately provided along a third direction orthogonal to the first direction and the second direction.
